(19) United States
(12) Patent Application Publication
(10) Pub. No.: US 2025/0349500 A1
(43) Pub. Date: Nov. 13, 2025

(54) MULTI-BEAM CHARGED PARTICLE MICROSCOPE DESIGN WITH A DETECTION UNIT FOR FAST COMPENSATION OF CHARGING EFFECTS

(71) Applicant: Carl Zeiss MultiSEM GmbH, Oberkochen (DE)

(72) Inventors: Felix MENKE, Oberkochen (DE); Thomas DIETERLE, Murrhardt (DE); Thomas SCHMID, Aalen (DE); Bjoern MIKSCH, Heidenheim (DE); Markus KOCH, Neu-Ulm (DE); Dirk ZEIDLER, Oberkochen (DE); Stefan SCHUBERT, Oberkochen (DE); Heiko BANZHAF, Gerstetten (DE); Andreas HAAS, Dischingen (DE)

(21) Appl. No.: 19/277,961

(22) Filed: Jul. 23, 2025

Related U.S. Application Data
(63) Continuation of application No. PCT/EP2024/025013, filed on Jan. 10, 2024.

(30) Foreign Application Priority Data
Feb. 6, 2023 (DE) 10 2023 200 945.5

(51) Int. Cl. H01J 37/21; H01J 37/10; H01J 37/147

(52) U.S. Cl. CPC H01J 37/21; H01J 37/10; H01J 37/1471; H01J 2237/216

(57) ABSTRACT

A multi-beam charged particle system with a secondary electron imaging system is configured to dynamically compensate charging effects. The multi-beam charged particle system comprises an improved cross-over detection system and a cross-over actuation mechanism, which are both connected to a contrast control module. The system allows for closed-loop control of an intensity distribution of a plurality of secondary electron beamlets within a cross-over or pupil plane. The disclosure can be applied to wafer inspection with multi-beam charged particle system.

### CROSS-REFERENCE TO RELATED APPLICATIONS

The present application is a continuation of, and claims benefit under 35 USC 120 to, international application No. PCT/EP2024/025013, filed Jan. 10, 2024, which claims benefit under 35 USC 119 of German Application No. 10 2023 200 945.5, filed Feb. 6, 2023. The entire disclosure of each of these applications is incorporated by reference herein.

### FIELD

The disclosure relates to a multi-beam charged particle microscope with improved imaging contrast and a method for the inspection of semiconductor features with improved image contrast.

### BACKGROUND

WO 2005/024881 discloses an electron microscope system which operates with a multiplicity of electron beamlets for the parallel scanning of an object to be inspected with a bundle of electron beamlets. The bundle of primary charged particle beamlets is generated by directing a primary charged particle beam onto a multi-beam forming unit, comprising at least one multi-aperture plate, which has a multiplicity of openings. One portion of the electrons of the electron beam is incident onto the multi-aperture plate and is absorbed there, and another portion of the beam transmits the openings of the multi-aperture plate and thereby in the beam path downstream of each opening an electron beamlet is formed whose cross section is defined by the cross section of the opening. The primary charged particle beamlets are focused by an objective lens on a surface of a sample and trigger secondary electrons or backscattered electrons to emanate as secondary electron beamlets from the sample, which are collected and imaged onto a detector. Each of the secondary beamlets is incident onto a separate detector element or group of detector elements, so that the secondary electron intensities detected therewith provide information relating to the surface of the sample at the location where the corresponding primary beamlet is incident onto the sample. The bundle of primary beamlets is scanned systematically over the surface of the sample and an electron microscopic image of the sample is generated in a typical approach for scanning electron microscopes.

Generally, the imaging contrast of a scanning electron microscope generally depends on the signal generated by secondary electrons, which generally depends on the secondary electron (SE) yield per primary electron and a geometrical collection efficiency of the electron microscope. The SE yield generally depends on material characteristics and the kinetic energy of the primary electrons. The SE yield may further have an angular component, i.e. the SE yield can be a function of the polar angle with respect to a surface normal to the sample. The secondary electron beamlets collected by the objective lens are then guided to a detector. The secondary electrons generated and extracted from the sample surface, however, are in many cases subject to charging effects at the sample surface, especially if the secondary electron yield is not in balance with incident current of the primary electrons. These charging effects can lead to a deterioration of the secondary electron beamlets and to reduced image contrast, an increase of crosstalk or even a complete loss of the secondary electron signal. Charging effects can become more and more deteriorating the image contrast in wafer inspection tasks during fabrication of integrated circuits. Such wafers typically comprise semiconductor materials, local capacities, and isolators, which may accumulate for example surface charges. In other examples, the target of an inspection task are wafers covered by photoresist, wherein photoresist accumulates local surface charges. Patent applications WO 2022/248141 and DE 102022114923.4 disclose monitoring methods to detect charging effects at such charging samples. US 2020/0411274 discloses a current detector arranged within a detection system by which also a detection of a decentering of charged particle beamlets is enabled. US 2020/0411274 discloses a high frequency adjustment of the projection system, using a spatially resolving detection system that uses a fraction of the signal impinging onto a spatially resolving image detector. DE 102 018124044 B3 proposes a deconvolution of crosstalk. However, in general, a deconvolution is only possible for minor charging effects. Generally, for a compensation of charging effects during the imaging of secondary electron beamlets, an electron-optical mechanism is used to maintain a high contrast at a secondary electron detector.

Different mechanisms have been proposed to improve an imaging contrast of a multi-beam electron microscope in presence of charging effects. U.S. Pat. No. 11,049,686, U.S. Pat. No. 10,896,800, U.S. Pat. No. 10,811,215 and WO 2021/239380 propose an arrangement of several active electrostatic or magneto-dynamic elements within a secondary electron imaging system. However, these systems can be relatively complex, or they might not allow a fast correction of deteriorated secondary electron beamlets with sufficient magnitude of correction. For example, U.S. Pat. No. 10,811,215 proposes secondary electron imaging system designs comprising up to nine electro-optical lenses.

Generally, elements for focus adjustment, image magnification and image rotation within a secondary electron imaging systems are well known. For example, U.S. Pat. No. 9,368,314, U.S. Pat. No. 7,601,972, U.S. Pat. No. 7,049,585, U.S. Pat. No. 6,992,290, US 2009/014649, or U.S. Pat. No. 8,362,425 mention zoom lenses and rotation compensators in secondary electron imaging systems, or provide simplified sketches of secondary electron imaging systems, like in US 2016/0268096. However, the examples of these references generally do not provide more than a raw conception of a secondary electron imaging system, which is not reduced to a practical design. Therefore, there remains a desire for a secondary imaging system of a multi-beam electron beam system which offers a high speed and large range for the compensation of charging effects.

### SUMMARY

The disclosure provides a multi-beam charged particle system and a method of operating a multi-beam charged particle system for image acquisition with relatively high contrast. The disclosure provides an improved imaging system design for imaging secondary electron beamlets generated from charging samples.

According to the disclosure, a multi-beam charged particle system can be configured to compensate charging effects during a scanning image acquisition. A multi-beam charged particle system according to the disclosure can comprise a charged-particle multi-beamlet generator for generating a plurality of primary charged particle beamlets. A multi-beam charged particle system according to the disclosure can comprise an object irradiation unit, which comprises a beam divider and an objective lens for forming a plurality of focus spots of primary charged particle beamlets in a primary image plane, in which a surface of a wafer can be arranged by a sample stage. During operation of a multi-beam charged particle system, secondary electrons are generated at a plurality of interaction volumes, formed by the plurality of focus spots of primary charged particle beamlets in a wafer. A multi-beam charged particle system according to the disclosure can further comprise a detection unit, configured for imaging the secondary electrons on an image sensor. The detection unit can comprise a cross-over detection system and a cross-over actuation mechanism, which are both connected to a contrast control module. The contrast control module can be configured to receive sensor information from the cross-over detection system and is configured to provide a control signal to the cross-over actuation mechanism. Thereby, the detection unit can be configured to form during use a feedback system for a dynamic compensation of a charging effect.

In an example, the detection unit is of reduced complexity and comprises only a first magneto-dynamic lens, a pair of magneto-dynamic lenses, the cross-over detection system and the cross-over actuation mechanism. The multi-beam charged particle system further comprises a voltage supply unit configured to provide during use a sample voltage (VS) to a wafer for adjusting a selected landing energy (EL) of primary charged particles over a large range between 200 eV, or even less and 2 keV or even more, for example 3 keV.

In an embodiment, a detection unit of a multi-beam charged particle beam system comprises at least one imaging lens for forming a plurality of focus spots of a plurality of secondary electron beamlets generated during use in an image plane of the detection unit (also called the secondary electron image plane). The detection unit further comprises an aperture stop arranged in a cross-over or pupil plane of the detection unit for filtering the plurality of secondary electron beamlets within the cross-over or pupil plane. With the aperture stop, an equal image contrast is achieved for each of the plurality of secondary electron beamlets. During an imaging operation with the multi-beam charged particle beam system, a pupil distribution of the plurality of secondary electron beamlets at the aperture stop plane can be decentered, for example due to a charging effect. The detection unit according to the embodiment therefore comprises a cross-over detection system connected to a contrast control unit, configured to generate during use a measurement signal of at least a lateral position of the pupil distribution of the plurality of secondary electron beamlets within the cross-over or pupil plane. The cross-over detection system is configured to provide during use the measurement signal to the contrast control unit. The detection unit according to the embodiment further comprises at least one cross-over actuation mechanism connected to the contrast control unit, configured to receive at least one driving signal from the contrast control unit for adjusting the lateral position of the pupil distribution within the cross-over or pupil plane. The contrast control unit is configured to determine from the measurement signal a displacement of the pupil distribution with respect to an optical axis of the detection unit. Such a displacement can for example be a given in presence of a charging effect of a wafer. The contrast control unit is further configured to determine the at least one driving signal from the displacement and to provide the driving signal to the at least one cross-over actuation mechanism. Thereby, a displacement is reduced or entirely compensated. The cross-over actuation mechanism within the detection unit is formed by a multi-pole deflector, a tilt actuator of a lens element, a position actuator of a lens element, and/or of the aperture stop.

In an example, the cross-over actuation mechanism comprises at least one deflector, arranged, and configured to adjust a lateral position of the pupil distribution of the plurality of secondary electron beamlets while keeping the focus points of each of the plurality of secondary electron beamlets at the secondary electron image plane at a predefined and constant position. For example, a single deflector can be arranged in an intermediate image plane of the detection unit to achieve this effect. In an example, the cross-over actuation mechanism comprises at least a first and a second deflector, configured to adjust a lateral position of the pupil distribution of the plurality of secondary electron beamlets while keeping the focus points of each of the plurality of secondary electron beamlets in the secondary electron image plane at a predefined and constant position. In an example, the cross-over actuation mechanism comprises a position or tilt actuator configured for changing the axial position or tilt angle of at least one movable element of the detection unit while keeping the focus points of each of the plurality of secondary electron beamlets at the image plane at a predefined and constant position. In an example, a single movable element is given by the aperture stop, which is in this example mounted on a position actuator for lateral movement of the aperture stop. Thereby, the aperture stop is centered in agreement to a displaced pupil distribution of the plurality of secondary electron beamlets, and an equal imaging contrast for each of the plurality of secondary electron beamlets is achieved. In an example, the cross-over actuation mechanism comprises at least a first and a second position or tilt actuator of a first and a second lens element. A combination of at least one deflector and at least one position or tilt actuator is possible as well.

In an embodiment, the cross-over detection system of the detection unit comprises a scintillator coating positioned in a cross-over or pupil plane and a monitoring camera, a plurality of absorber segments arranged around the aperture stop and connected to ampere meters, a retractable detection system (such as a cross-over detection system with a spinning wheel), a voltage supply to generate a voltage potential within the aperture stop, and/or a deflector to deflect the plurality of secondary electron beamlets into a second monitoring plane. Thereby, at least a displacement of a pupil distribution can be measured and determined.

In an example, a scintillator coating is arranged in the periphery of an opening of the aperture stop and a monitoring camera is arranged to form an image of the excited light from the scintillator coating. Such a camera system comprising a CMOS sensor and an optical imaging system can be arranged within the vacuum compartment of the detection unit.

In an example, the cross-over detection system comprises a plurality of absorber segments arranged in the periphery of an aperture opening of the aperture stop. Each absorber segment is connected to an ampere meter. During use, and in presence of a displacement of the pupil distribution of the plurality of secondary electron beamlets, the absorbed secondary electrons generate different currents within each segment. From the different currents, a displacement of the pupil distribution can be derived.

In an example, the cross-over detection system comprises the deflector configured to deflect the plurality of secondary electron beamlets on a second monitoring plane adjacent to a cross-over plane, and a monitoring camera arranged to form a digital image of the second monitoring plane.

In an example of a cross-over detection system, the aperture stop is connected to a voltage supply. With the voltage supply, at least a first and a second voltage can be supplied to the aperture stop in for example an alternating manner. The aperture stop with a voltage different from beam tube elements arranged upstream and downstream of the secondary electron beam path forms an Einzel lens. In case of a decentered pupil distribution, the Einzel lens generated by the aperture stop has the effect of a displacement of the positions of the focus spots of the plurality of secondary electron beamlets in the (second) image plane of the detection unit. This displacement can be detected, and a corresponding displacement of the pupil distribution is determined.

A multi-beam charged particle beam system according to the disclosure can comprise an object irradiation unit for forming a plurality of primary focus spots in an image plane, a wafer stage configured for holding and positioning during use a surface of a wafer in the image plane of the object irradiation unit, and a detection unit according to the embodiments described above.

In an embodiment, the disclosure provides a method of operating a multi-beam charged particle system. The method can comprise imaging a plurality of secondary electron beamlets excited during use from a surface of a wafer and to from a plurality of focus spots of the plurality of secondary electron beamlets in an image plane of the detection unit. The method can further comprise starting and performing of a scanning image acquisition and detecting a pupil distribution of the plurality of secondary electron beamlets at a cross-over plane with a cross-over detection system during the image acquisition. The method can further comprise adjusting a lateral position of a pupil distribution in a cross-over plane while keeping the focus points of each of the plurality of secondary electron beamlets in the image plane at a predefined and constant position. The method can further comprise selecting an imaging setting including selection of a landing energy EL of primary charged particles from a large range of landing energies. The method can further comprise adjusting a deceleration field close to the surface of a wafer by a voltage supply unit for the supply of a voltage to the wafer sample holder. The method can further comprise adjusting at least one lens power of at least one magneto-dynamic projection lens of the detection unit in accordance with the selected landing energy EL. In an example, detecting the pupil distribution in a cross-over plane with a cross-over detection system is performed during a fly-back time of the scanning image acquisition. In an example, detecting the pupil distribution is continuously performed during the scanning image acquisition. Thereby, a feed-back loop for a compensation of a charging effect can be provided with a signal for performing the step of adjusting the lateral position of the pupil distribution in the cross-over plane.

The disclosure can provide multi-beam charged particle beam system comprising an object irradiation unit for forming a plurality of primary focus spots in an image plane, a wafer stage configured for holding and positioning during use a surface of a wafer in the image plane of the object irradiation unit, a detection unit and a contrast control unit configured to execute a method of operating a multi-beam charged particle system according to a method provided herein. The multi-beam charged particle beam system can further comprise a voltage supply unit configured to supply a sample voltage via the sample stage to the wafer sample. Thereby, a landing energy of primary electrons can be adjusted in a wide range.

In an embodiment, the disclosure provides a method of calibrating a cross-over monitoring system and a cross-over actuation mechanism. With the method, a measurement signal generated and provided by a cross-over monitoring system is calibrated according to a displacement of a pupil distribution of the plurality of secondary electron beamlets. With the method, a driving signal for a cross-over actuation mechanism is calibrated according to an effect of the cross-over actuation mechanism on a displacement of a pupil distribution of the plurality of secondary electron beamlets. By calibrating both steps, the determination of a displacement from a measurement signal and an effect of a driving signal to a displacement, a feed-back loop for a method of operating a multi-beam charged particle beam system configured for reducing a charging effect is enabled.

Embodiments or examples of the disclosure provide a multi-beam charged particle beam system and a method of operating a multi-beam charged particle beam system with improved image contrast. The disclosure can allows a wafer inspection, including charging wafer samples, with higher precision and with a higher accuracy.

It will be understood that the disclosure is not limited to the embodiments and examples but comprises also combinations and variations of the embodiments and examples.

### BRIEF DESCRIPTION OF THE DRAWINGS

Embodiments of the present disclosure will be explained in more detail with reference to drawings, in which:

FIG. 1 is a schematic sectional view of a multi-beam charged particle system;

FIG. 2 illustrates some details of a multi-beam charged particle beam system;

FIG. 3 illustrates an effect of a charging of a sample;

FIG. 4 illustrates a detector with an optical relay system;

FIG. 5 illustrates an example of a detection unit;

FIGS. 6A-6H illustrate an example of a detection unit;

FIG. 7 illustrates examples of a cross-over detection system;

FIGS. 8A-8B illustrate examples of a cross-over detection system;

FIGS. 9A-9B illustrate a scanning operation;

FIG. 10 illustrates an example of a cross-over detection system and method;

FIG. 11 illustrates an example of a method; and

FIG. 12 illustrates an example of a method according to the fifth embodiment.

### DETAILED DESCRIPTION

In the exemplary embodiments of the disclosure described below, components similar in function and structure are indicated within reason by similar or identical reference numerals.

Some array elements, for example the plurality of primary charged particle beamlets, are identified by a reference number. Depending on the context, the same reference number may also identify a single element out of the array elements. Each primary charged particle beamlet (3.1, 3.2, 3.3) is one beamlet of the plurality of primary charged particle beamlets (3).

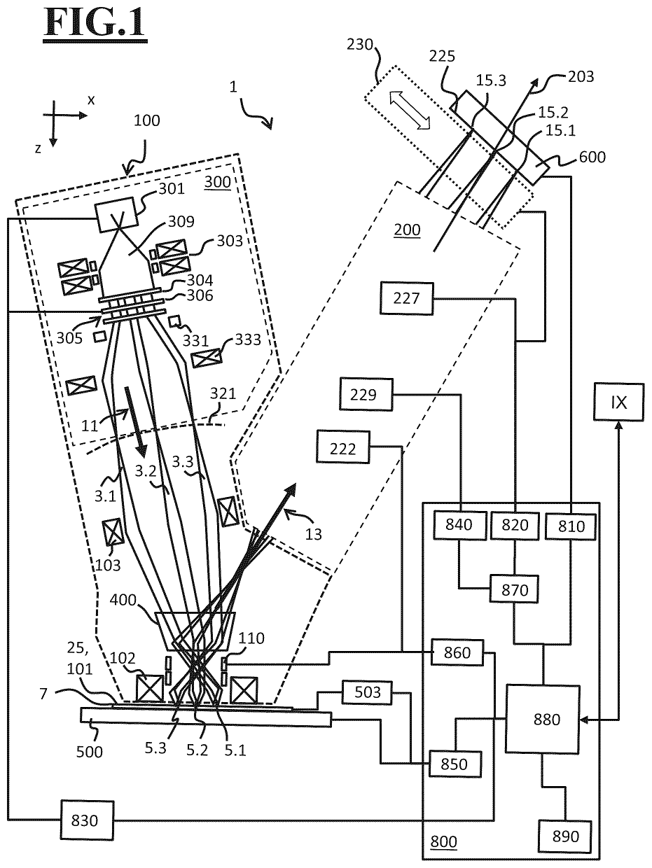

The schematic representation of FIG. 1 illustrates certain features and functions of a multi-beam charged-particle system 1. It is to be noted that the symbols used in the figure have, in general, been chosen to symbolize their respective functionality. The type of system shown is that of a multi-beam scanning electron microscope using a plurality of primary charged particle beamlets 3 for generating a plurality of primary charged particle beam spots 5 on a surface 25 of an object 7, such as a wafer or mask substrate located with a top surface 25 in an object plane 101 of an objective lens 102. For simplicity, only three primary charged particle beamlets 3.1 to 3.3 and three primary charged particle beam spots 5.1 to 5.3 are shown. The features and functions of multi-beamlet charged-particle system 1 can be implemented using electrons or other types of primary charged particles such as ions, such as Helium ions. Further details of the microscope system 1 are provided in International Patent application WO 2022/262970, filed on Jun. 16, 2021, which is hereby fully incorporated by reference.

The system 1 comprises an object irradiation unit 100 and a detection unit 200 and a secondary electron beam divider or beam splitter unit 400 for separating the secondary charged-particle beam path 13 from the primary charged-particle beam path 11. The object irradiation unit 100 comprises a charged-particle multi-beam generator 300 for generating the plurality of primary charged-particle beamlets 3 and is adapted to focus the plurality of primary charged-particle beamlets 3 on the object plane 101, in which the surface 25 of an object or wafer 7 is positioned by a sample stage 500.

The primary beam generator 300 produces a plurality of primary charged particle beamlet spots in an intermediate image surface 321. The primary beamlet generator 300 comprises at least one source 301 of primary charged particles, for example electrons. The at least one primary charged particle source 301 emits a diverging primary charged particle beam, which is collimated by at least one collimating lens 303 to form a collimated or parallel primary charged particle beam 309. The collimating lens 303 usually comprises (or consists of) one or more electrostatic or magnetic lenses, or a combination of electrostatic and magnetic lenses. The collimated primary charged particle beam 309 is incident on the primary multi-beam forming unit 305. A multi-beam generating unit 305 is for example explained in US 2019/0259575, and in U.S. Pat. No. 10,741,355, which are both hereby incorporated by reference. The multi-beam forming unit 305 comprises a first multi-aperture plate or filter plate 304 illuminated by the collimated primary charged particle beam 309. The first multi-aperture plate or filter plate 304 comprises a plurality of apertures in a raster configuration for generation of the plurality of primary charged particle beamlets 3, which are generated by transmission of the collimated primary charged particle beam 309 through the plurality of apertures. The multi-beamlet forming unit 305 comprises at least one further multi-aperture plate 306, which is located, with respect to the direction of movement of the electrons in beam 309, downstream of the first multi-aperture or filter plate 304. For example, a second multi-aperture plate 306 comprises for example four or eight of electrostatic elements for each of the plurality of apertures, for example to deflect each of the plurality of beamlets individually. The multi-beamlet forming unit 305 is further configured with an adjacent electrostatic field lens 331, which is in some examples combined in the multi-beamlet forming unit 305. Together with a second field lens 333, the plurality of primary charged particle beamlets 3 is focused in or in proximity of the intermediate image surface 321. The primary charged-particle source 301 and each of the active multi-aperture plates 306 are controlled by control unit 830.

The plurality of focus points of primary charged particle beamlets 3 passing the intermediate image surface 321 is imaged by field lens group 103 and objective lens 102 into the object plane 101, in which the surface 25 of the object 7 is positioned. A decelerating electrostatic field is generated between the objective lens 102 and the object surface 25 by application of a voltage to the object by the sample voltage supply 503. With the decelerating electrostatic field generated by sample voltage supply 503, a landing energy EL of primary electrons is adjusted to for example below 1 keV, below 800 eV, below 500 eV, below 300 eV or even less.

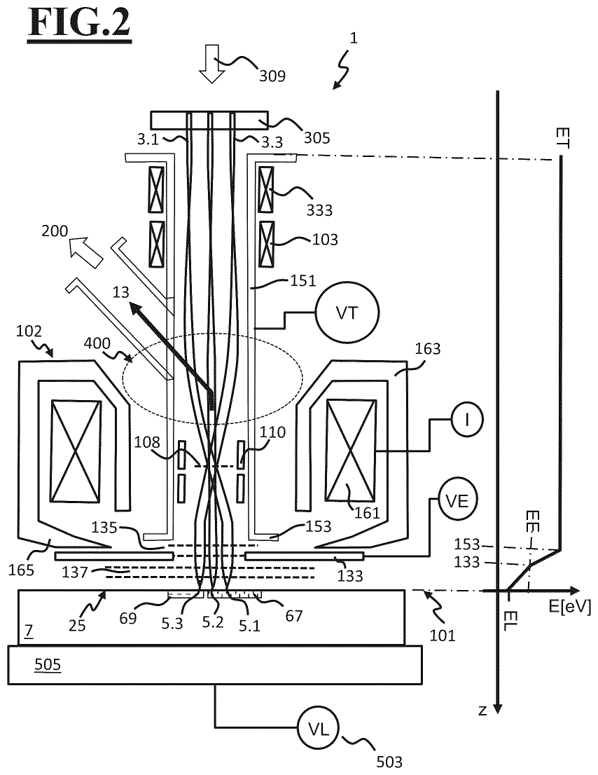

FIG. 2 illustrates certain details of the decelerating electrostatic field generated. From a collimated electron beam 309, a plurality of primary charged particle beamlets 3 is generated by the multi-aperture arrangement 305. For simplicity, only 3 beamlets 3.1 to 3.3 are shown, but there can be more beamlets, for example more than 60, more than 90, or even more than 300 beamlets. A beam tube 151 is provided downstream of the multi-aperture arrangement 305, the beam tube 151 being connected to a voltage supply with the first or tube voltage VT. From the entrance of a beam tube 151, the plurality of primary charged particle beamlets 3 is at a constant kinetic energy ET until the exit opening 153 of the beam tube 151. The kinetic energy ET of the primary charged particle beamlets 3 during passing the beam tube 151 is for example 20 KeV, 30 keV or more.

The plurality of primary charged particle beamlets 3 are imaged and focus points 5.1 to 5.3 are formed in an image plane 101 by field lenses 333 and 103, and by objective lens 102. The objective lens 102 is of the type of a magnetic lens with a coil 161 and a pole shoe 163 with a lower pole shoe segment 165, forming an axial gap for the magnetic field. A current I is provided during use to the coil 161 to generate the focusing magnetic field (not shown). Other types of magnetic lenses are possible as well, for example radial gap lenses for generation an immersion lens field, or magnetic lenses with several coils and pole shoes. Upstream or partially integrated in the objective lens 102, a beam divider 400 is arranged, configured to separate the secondary electrons along secondary electron beam path 13 to detector unit 200. Below the lower pole shoe segment 165, an electrode 133 is provided, connected to a voltage supply for providing a second voltage VE to the electrode. In the example shown, the electrode 133 is provided as separate electrode.

After leaving the beam tube 151, the plurality of primary charged particle beamlets 3 is decelerated from kinetic energy ET to a second kinetic energy EE (see energy plot on the right side of FIG. 2). The voltage difference between VT and VE is generally responsible for the generation of a first electric field 135, illustrated in FIG. 2 with the equipotential lines of the first electric field 135. The first electrical field vectors are almost parallel to the propagation direction of the primary charged particle beamlets 3 and generate a decelerating force to the primary charged particles. The first voltage VE is typically adjusted such that the second kinetic energy EE is in a range below 5 keV, below 3 keV or even below 2 keV. The sample voltage supply 503 provides a third sample voltage VL to a sample mounting platform 505 for holding and contacting during use a wafer 7. At the surface 25 of the wafer 7, a first material composition 67 is arranged under a first set of primary charged particle beamlets 3.1 and 3.2, and a second material composition 69 is arranged under a second set of primary charged particle beamlet comprising primary charged particle beamlet 3.3. According to the voltage difference between VL and VE, a second electrical field 137 is generated, which is almost parallel to the propagation direction of the primary charged particle beamlets 3 and generates a decelerating force to the primary charged particles. The third or sample voltage VL is adjusted such that the third kinetic energy or landing energy EL of the primary electrons is adjusted in a range below 800 eV, below 300 eV or even below 100 eV. The electrical fields 135 and 137 both form a decelerating field to reduce the kinetic energy of the primary charged particle beamlets 3 before impinging on the sample surface 25 arranged in the image plane 101, such that a high resolution is achieved. The first electrical field 135 also forms an accelerating field on secondary electrons extracted from the wafer 7. The second electrical field 137 forms an extraction field for extracting and accelerating secondary electrons from the wafer 7. The second field 137 is therefore also called the extraction field 137.

The example illustrated in FIG. 2 shows a multi-beam charged particle beam system 1 with a two-stage deceleration field 135 and 137 and an additional electrode 133. In another example only a single decelerating or extraction field 137 is generated between exit aperture 153 of the beam tube 151 and a sample 7 mounted on the sample platform 505. In this case, the exit aperture 153 of the beam tube 151 has the role of the electrode 133 for the extraction field 137.

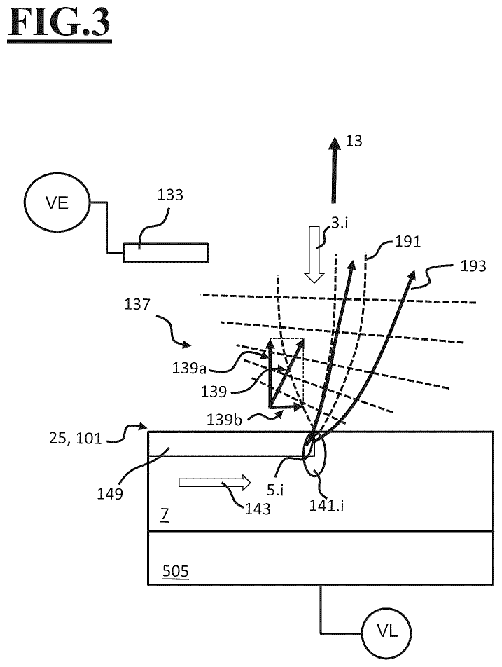

The extraction mechanism of secondary electrons is further illustrated in FIG. 3 in the presence of a charging effect. A primary charged particle beamlet 3.i is focused to focus point 5.i and impinges on the surface 25 of wafer 7 and forms an interaction volume 141.i within the wafer 7. During the operation at the low landing energies EL below 800 eV, below 300 eV or even below 100 eV, the interaction volume 141.i has a small extension below 5 nm or even less. Without any surface charging effects, the second or extraction field 137 extracts and accelerates secondary electrons generated in the interaction volume 141.i along electron trajectories 191 (dashed lines in FIG. 3) in opposite propagation direction to the primary electron beam direction. FIG. 3 illustrates the situation when a sample is charged by the scanning irradiation with primary charged particle beamlet 3.i. The primary beamlet 3.i is scanned in scanning direction 143 and leaves a scanned surface segment 149 with a residual charge. This charging of the scanned surface segment 149 deteriorates the extraction field 137 generated between wafer sample 7 and electrode 133 and causes a local tilt to an extraction field vector 139. The effect of the extraction field vector 139 is more pronounced to the secondary electron beamlets having a lower kinetic energy compared to the primary electrons of the impinging primary beamlet 3.1. Therefore, the secondary electron trajectories 193 (bold lines) in presence of a charging effect are deflected and have a tilt component. As an effect, the virtual displacement of an angular distribution of the secondary electrons leads to a displacement of a secondary electron beamlet in a cross-over or pupil plane of the detection unit. In FIG. 3, the effect of a negative charging is illustrated, with an additional vector component to the extraction field vector in positive line scanning direction 143. In an equivalent way, a positive charging would add a vector component to the extraction field vector in negative line scanning direction 143.

The object irradiation system 100 of the multi-beam charged particle beam system 1 shown in FIGS. 1 and 2 further comprises a collective multi-beam raster scanner 110 in proximity of a beam cross over 108 by which the plurality of charged particle beamlets 3 can be deflected in scanning direction 143 perpendicular to the propagation direction of the charged particle beamlets. The propagation direction of the primary beamlets throughout the examples is in positive z-direction. Objective lens 102 and collective multi-beam raster scanner 110 are centered at an optical axis (not shown) of the multi-beam charged-particle system 1, which is perpendicular to wafer surface 25. The plurality of primary charged particle beamlets 3, forming the plurality of beam spots 5 arranged in a raster configuration, is scanned synchronously over the wafer surface 25. In an example, the raster configuration of the focus spots 5 of the plurality of J primary charged particle 3 is a hexagonal raster of about one hundred or more primary charged particle beamlets 3, for example J=91, J=100, or J approximately 300 or more beamlets. The primary beam spots 5 have a distance about 6 μm to 45 μm and a diameter of below 5 nm, for example 3 nm, 2 nm or even below. In an example, the beam spot size is about 3 nm, and the distance between two adjacent beam spots is 8 μm. At each scan position of each of the plurality of primary beam spots 5, a plurality of secondary electrons is generated, respectively, forming the plurality of secondary electron beamlets in the same raster configuration as the primary beam spots 5. The intensity of secondary charged particle beamlets generated at each beam spot 5 depends on the intensity of the impinging primary charged particle beamlet 3, illuminating the corresponding spot 5, the material compositions 67, 69 and topography of the object 7 under the beam spot 5, and the charging condition of the sample at the beam spot 5. The plurality of secondary charged particle beamlets are accelerated by the same electrostatic field between objective lens 102 and object surface 25 and are collected by objective lens 102 and pass the first collective multi-beam raster scanner 110 in opposite direction to the primary beamlets 3. The plurality of secondary beamlets is scanning deflected by the first collective multi-beam raster scanner 110. The plurality of secondary charged particle beamlets is then guided by secondary electron beam divider or beam splitter unit 400 to follow the secondary beam path 13 to the detection unit 200. The plurality of secondary electron beamlets is travelling in opposite direction from the primary charged particle beamlets 3 with kinetic energy ES=ET−EL, and the beam splitter unit 400 is configured to separate the secondary beam path 11 from the primary beam path usually via magnetic fields or a combination of magnetic and electrostatic fields.

Detection unit 200 images the secondary electron beamlets onto the image sensor 600 to form there a plurality of secondary charged particle image spots 15. The detector or image sensor 600 is arranged in a secondary electron image plane 225 of the detection unit 200. The secondary electron image plane 225 can be tilted with respect to a plane perpendicular to the optical axis 203 of the detection unit 200. Thereby, a Scheimpflug condition with respect to the image plane 101 of the object irradiation unit 100 can be satisfied. The detector or image sensor 600 comprises a plurality of detector pixels or individual detectors. For each of the plurality of secondary charged particle beam spots 15, the intensity is detected separately, and the property of the object surface 25 is detected with high resolution for a large image patch of the object 7 with high throughput. For example, with a raster of 10×10 beamlets with 8 μm pitch, an image patch of approximately 88 μm×88 μm is generated with one image scan with collective multi-beam raster scanner 110, with an image resolution of for example 2 nm or below. The image patch is sampled with half of the beam spot size, thus with a pixel number of 8000 pixels per image line for each beamlet, such that the image patch generated by 100 beamlets comprises 6.4 gigapixel. The digital image data is collected by control unit 800. Details of the digital image data collection and processing, using for example parallel processing, are described in international patent application WO 2020151904 A2 and in U.S. Pat. No. 9,536,702, which are hereby incorporated by reference.

Detection unit 200 further comprises at least a second raster scanner 222, which is connected to scanning control unit 860. Scanning control unit 860 is configured to compensate a difference in the scanning deflection power of the first scanning deflector 110 in the common beam path, such that the positions of the plurality secondary electron focus spots 15 are kept constant at image sensor 600. The difference in the scanning deflection power of the first scanning deflector 110 arises from the difference between the kinetic energy ET of primary electrons with respect to the kinetic energy ES of secondary electrons. The system 1 may further comprise an optionally retractable monitoring system 230. Monitoring systems and monitoring methods to detect charging effects at such charging samples are further described in patent applications WO 2022248141 A1 and DE 102022114923.4, which are hereby fully incorporated by reference. The detection unit 200 is described in more detail below.

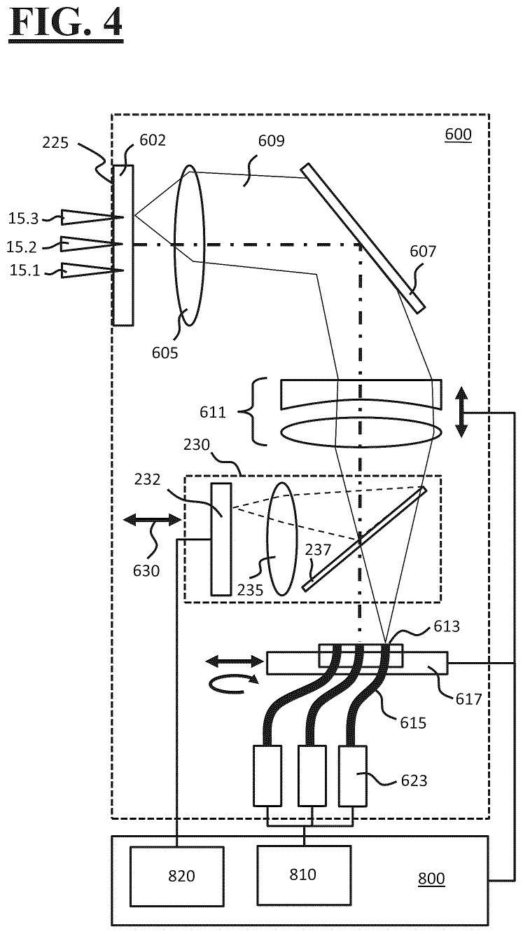

The image sensor 600 is configured by an array of sensing areas in a pattern compatible to the raster arrangement of the secondary electron beamlets focused by the detection unit 200 onto the image sensor 600. This enables a detection of each individual secondary electron beamlet independent from the other secondary electron beamlets incident on the image sensor 600. The image sensor 600 illustrated in FIG. 1 can be an electron sensitive detector array such as a CMOS or a CCD sensor. Such an electron sensitive detector array can comprise an electron to photon conversion unit, such as a scintillator element or an array of scintillator elements. In another embodiment, the image sensor 600 can be configured as electron to photon conversion unit or scintillator plate arranged in the focal plane of the plurality of secondary electron particle image spots 15. In this embodiment, as shown in FIG. 4, the image sensor 600 can further comprise a relay optical system comprising collection lenses 605 and zoom lens 611 for imaging and guiding the photons generated by the electron to photon conversion unit 602 at the secondary charged particle image spots 15 on dedicated photon detection elements 623, such as a plurality of photomultipliers or avalanche photodiodes. Such an image sensor is disclosed in U.S. Pat. No. 9,536,702, which is cited above and incorporated by reference. The image sensor is further configured with an optionally extractable monitoring system 230, comprising a beam divider mirror 237, an imaging lens 235 and a CMOS sensor 232 with high resolution.

During an acquisition of an image patch by scanning the plurality of primary charged particle beamlets 3, the stage 500 is optionally not moved, and after the acquisition of an image patch, the stage 500 is moved to the next image patch to be acquired. In an alternative implementation, the stage 500 is continuously moved in a second direction while an image is acquired by scanning of the plurality of primary charged particle beamlets 3 with the collective multi-beam raster scanner 110 in a first direction. Stage movement and stage position is monitored and controlled by sensors known in the art, such as Laser interferometers, grating interferometers, confocal micro lens arrays, or similar.

During an image scan, the control unit 800 is configured to trigger the image sensor 600 to detect in predetermined time intervals a plurality of timely resolved intensity signals from the plurality of secondary electron beamlets, and the digital image of an image patch is accumulated and stitched together from all scan positions of the plurality of primary charged particle beamlets 3.

The control unit 800 of the multi-beamlet charged-particle system 1 further comprises an-imaging control module 810, configured to receive the data streams from the image sensor 600 and to generate a digital image of the surface of the sample 7 during operation; a secondary beam-path control module 840, configured to control the detection unit 200; a primary beam-path control module 830, configured to control the elements of the object irradiation unit 100; a stage control module 850, configured to control the stage positioning and alignment, and including control of the sample voltage supply unit 503; a scanning operation control module 860, configured to control a scanning operation by the first collective multi-beam raster scanner 110 and the second deflection system 222; a control operation processor unit 880, configured to execute inspection tasks of samples, and configured to control the modules 810, 820, 830, 840, 850, 860 and a memory 890 for storing software, instructions and image data. The control operation processor unit 880 is further connected to an interface IX for exchange of data, instructions, software or user interaction.

The detection unit 200 comprising a cross-over detection system 227 and a cross-over actuation mechanism 229, which are both connected to a contrast control module 870. The contrast control module 870 is configured to receive sensor information from the cross-over detection system 227 and is configured to provide a control signal to the cross-over actuation mechanism 229. Thereby, the detection unit 200 is configured to form during use a feedback system for a dynamic compensation of charging effects. The contrast control module 870 is further configured to receive instructions from the control operation processor unit 880 to control a compensation of charging effects during the imaging of secondary electrons onto the image sensor 600. In an example, the contrast control module 870 is connected to a sensor module 820, connected to the cross-over detection system 227. In an example illustrated in FIG. 1, the contrast control module 870 is not directly connected to the cross-over actuation mechanism 229, but connected to the secondary beam-path control module 840, which is then connected to the cross-over actuation mechanism 229.

When sample charging occurs as illustrated in FIG. 3, the trajectories of the secondary electron path can be distorted and experience an additional tilt component. As a result, the detector 600 is no longer correctly hit by the secondary electron beamlets. For example, the additional tilt components lead to non-telecentric secondary electron beamlets with secondary electron beamlets impinging on the secondary electron image plane 225 at an oblique angle. For example, the additional tilt components lead to a displacement of the focus spots 15 of the secondary electron beamlets 9 impinging on the secondary electron image plane 225. In a worst case, this can result in dark images, or in large crosstalk.

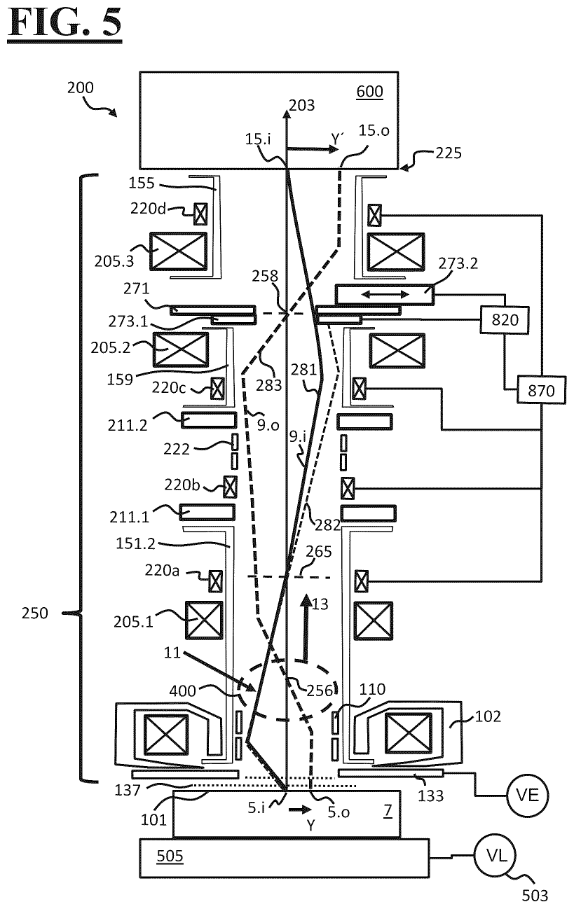

FIG. 5 illustrates an example of a first embodiment. FIG. 5 illustrates the detection unit 200 and further components already shown in FIG. 1 or 2, which are labelled by same reference numbers and reference is made also to the description of FIGS. 1 and 2. The primary charged particle beamlets are schematically shown by primary beam path 11. The FIG. 5 illustrates the secondary electron beam path at the example of two selected electron trajectories 281 and 283 of two secondary electron beamlets 9.i and 9.o at a first landing energy EL of primary electrons. There are many more secondary electron beamlets, corresponding to the plurality of primary charged particle beamlets, which are focused onto the surface 25 of a sample 7 (with only to focus points 5.o and 5.i shown). The detection unit 200 comprises a second branch 151.2 of the common beam tube 151, which is connected to a voltage supply line and set to tube voltage VT (see also FIG. 2). VT can for example be ground potential. Through the tube 151, primary charged particles propagate with constant high kinetic energy of for example E1=30 keV. Through the tube 151, secondary electrons propagate with constant high kinetic energy of for example E2=E1−EL, for example with E2 between 27 keV and 30 keV. The detection unit 200 further comprises a second beam tube segment 159 and a third beam tube segment 155. Between the second branch 151.2 and the second beam tube segment 159, a first fast electrostatic lens element 211.1 is arranged. Between the second beam tube segment 159 and the third beam tube segment 155, a second fast electrostatic lens element 211.2 is arranged. For the first and second fast electrostatic lenses 211.1 and 211.2, reference is made to German patent application 102022213751.5, filed on Dec. 16, 2022, which is incorporated here within by reference. Upstream of the first fast electrostatic lens element 211.1 in propagation direction of the secondary electron path 13, a first magnetic projection lens 205.1 is arranged. Between the first and second fast electrostatic lens 211.1 and 211.2, the second scanning deflector 222 is arranged. In this example, the second scanning deflector 222 is a two-stage electrostatic octupole scanner. The detection unit 200 further comprises at least one static deflector or multi-pole corrector 220. In the example illustrated in FIG. 5, four multi-pole correctors 220a, 220b, 220c and 220d are shown for quasi-static adjustment of a secondary electron beam path. A pair of two further magnetic projection lenses 205.2 and 205.3 are configured to form the focus spots 15.i, 15.o of the secondary electron beamlets 9.i, 9.o on the secondary electron image plane 225 and to adjust an image rotation of the secondary electrons beamlets, induced by for example a change of an image plane 101 by objective lens 102. The three magnetic projection lenses 205.1, 205.2 and 205.3 and the at least one quasi-static multi-pole corrector 220 are connected to and controlled by the secondary beam-path control module 840. The elements are arranged and centered around the optical axis 203 of the detection unit 200, which is for simplicity shown as a straight line; however, the optical axis 203 can also comprise a curved segment for example within the beam divider 400.

Within the detection unit 200, at least a first cross-over 256 and a second cross-over 258 of the secondary electron beamlets 9 are formed. A cross-over is defined as the position along the secondary electron beam path 13, at which the plurality of secondary electron beamlets 9 intersect each other. Generally, a pupil plane or cross-over plane 256 or 258 is defined by the cross-over formed by the intersection of the secondary electron trajectories starting perpendicular to the image plane 101. An example is illustrated by trajectory 283 of secondary electron beamlet 9.o, which is starting at focus point 5.o perpendicular to the image plane 101, having two cross-overs 256 and 258 with the optical axis 203, which is perpendicular to the primary image plane 101. In another example, a detection unit 200 comprises more than two cross-overs, for example a third cross-over.

In the example of FIG. 5, an aperture stop 271 is positioned within a plane perpendicular to the optical axis of the secondary electron beam path 13 at the second cross-over position 258. The aperture stop 271 is typically of circular shape, but other shapes are possible as well. The aperture stop 271 has the function to serve during use as a contrast or pupil filter, with allows passage of identical angular intensity distributions of each secondary electron beamlet 9 and is thereby responsible for an identical image contrast for each secondary electron beamlet 9. Some examples of aperture stops 271 are disclosed in patent application PCT/EP2023/025426 which is hereby incorporated by reference.

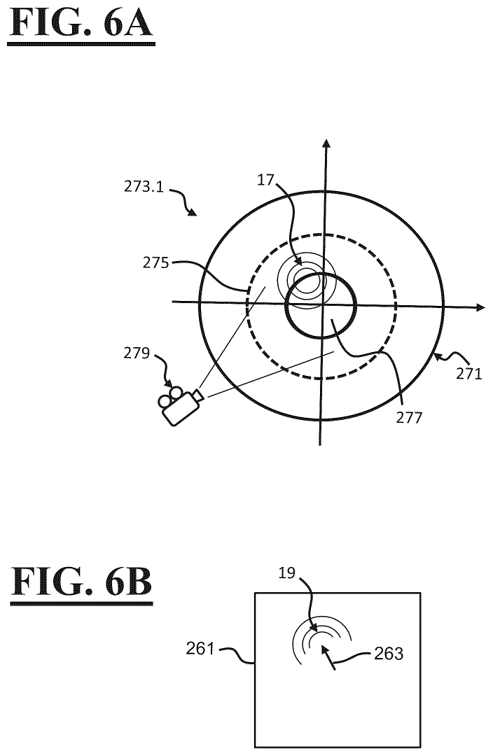

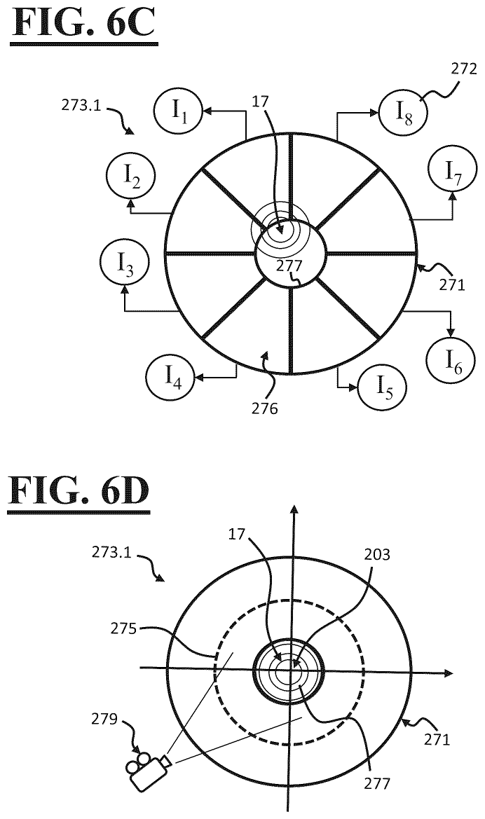

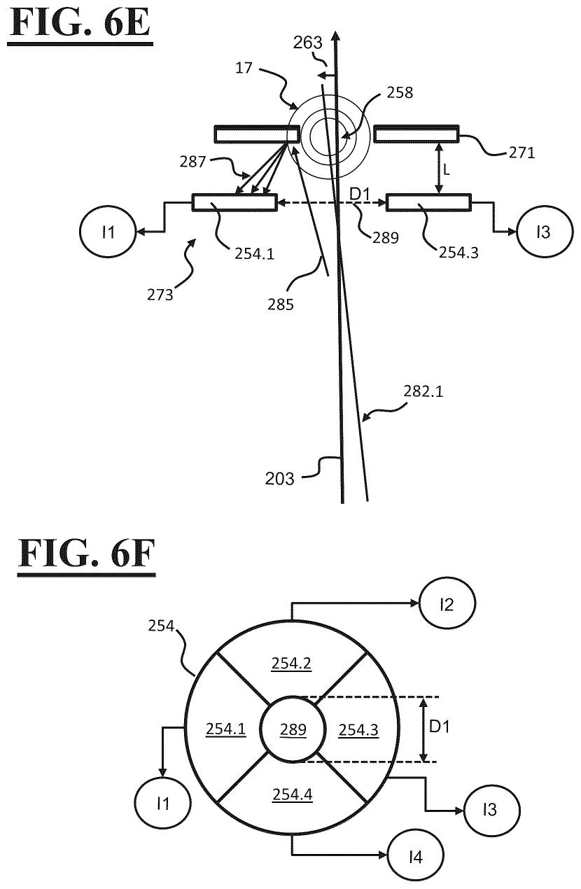

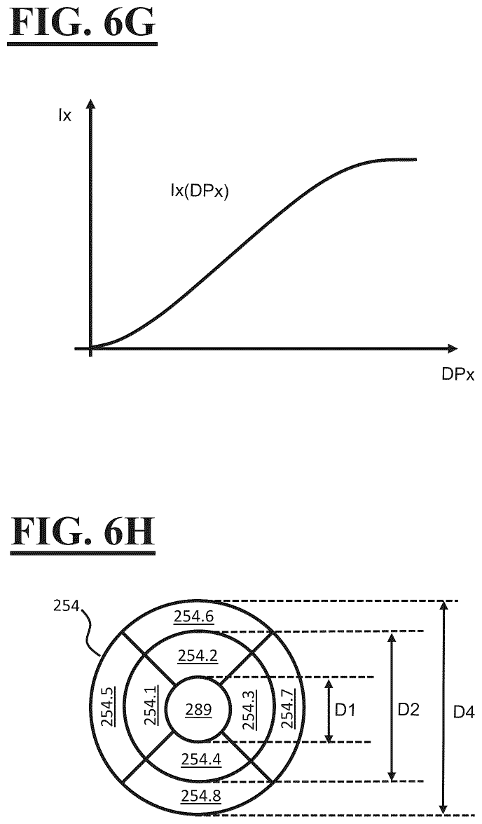

In presence of charging effects, however, the secondary electron beamlets can comprise an additional tilt component at the image plane 101, which corresponds to a displacement of the intensity distribution in a cross-over or pupil plane 258. In such case, the aperture stop 271, which is centered at the optical axis 203, filters out a decentered or asymmetrical part of the intensity distribution of the plurality of secondary electron beamlets 9. Therefore, detection unit 200 further comprises at least one cross-over detection system 273. In FIG. 5, two cross-over detection system 273.1 and 273.2 are illustrated. Some examples of a first cross-over detection system 273.1 are illustrated in FIG. 6. FIG. 6A shows a first example. In the first example, an electron-to-photon converter 275 is arranged on the aperture stop 271 in the circumference of the aperture filter opening 277. The electron-to-photon converter 275 is for example a scintillator coating provided at the entrance side of the aperture stop 271. In this example, the intensity distribution of the secondary electrons within the pupil plane (short: the pupil distribution) 17 is decentered due to charging effects at the sample. The pupil distribution 17 has an overlapping portion with the scintillator coating 275 and secondary electrons are converted into light. The light excited from the scintillator coating 275 is imaged by a camera 279 comprising an imaging optical system and a high-resolution optical sensor, such as a CMOS sensor. Such a camera 279 can be very small, comparable to a smartphone camera, and is arranged in the vacuum chamber. An example of an image data 261 obtained by camera 279 is shown in FIG. 6B, showing the intersection 19 of the pupil distribution 17 with the scintillator coating 275 of aperture stop 271. From the intersection 19, a beam displacement 263 in the pupil plane can be derived. The cross-over detection system 273.1 of the first example therefore comprises an electron-to-light converter coating 275 and a camera 279, configured to form an image of the electron-to-light converter coating 275 on a sensor and connected to the sensor module 820 (see FIG. 5). The sensor module 820 is configured to derive a displacement vector 263 from the image data 261 provided by the camera 279. The sensor module 820 is connected to contrast control module 870, which is configured to generate from the displacement vector 263 provided by the sensor module 820 a control signal. The contrast control module 870 is connected to at least one cross-over actuation mechanism 220, which is in the example of FIG. 5 formed by at least one multipole deflector 220a, 220b or 220c. The at least one multipole deflector 220a, 220b or 220c are arranged and configured to adjust the intensity distribution at pupil plane 258 while keeping the focus spots 15 on the secondary electron image plane 225 at constant position.

FIG. 6C illustrates a further example of the cross-over detection system 273.1. In the second example, the aperture stop 271 is provided with segments 276 of conductive absorber coatings in the circumference of aperture filter opening 277. The individual segments 276 are isolated with respect to each other. Each segment is connected via a current measurement sensor or ampere meter 272 to ground level. Secondary electrons impinging on a segment are absorbed there and generate a current, for example currents I1 to I8 from the eight segments shown in FIG. 6C. The sensor segments act similar to a quadrant sensor. From the intensity signals I1 to I8, the displacement vector 263 of the pupil distribution 17 can be derived. A cross-over detection system 273 is therefore generally configured to generate a plurality of signals representing the pupil distribution 17 of the secondary electron beamlets within the pupil plane at the second cross over position 258. The signals are received by sensor module 820. The sensor module 820 is configured to derive a center of gravity of the intensity distribution 17 and a displacement vector 263 of the pupil distribution 17. The sensor module 820 is connected to contrast control module 870. The contrast control module 870 is configured to derive and generate a plurality of control signals for a cross-over actuation mechanism 220, by which for example a position of the pupil distribution 17 of the secondary electron beamlets within the pupil plane is adjusted. In the example of FIG. 5, the cross-over actuation mechanism is formed by the at least one quasi-static multi-pole corrector 220a, 202b or 220c. For example, the first multi-pole corrector 220a is arranged at an intermediate image plane 265 of the detection unit 220. At such a position, the tilt angle of each secondary electron beamlet 9 can be adjusted. An example is illustrated at trajectory 282 before an actuation of the first multi-pole corrector 220a and with trajectory 281 after actuation of the first multi-pole corrector 220a. Thereby, the mean propagation angles of each secondary electron beamlet 9 can be commonly adjusted. Since the first multi-pole corrector 220a is arranged in an intermediate image plane 265, the positions of the focus points 15.i and 15.o of the secondary electron beamlets 9.i and 9.o at the secondary electron image plane 225 are not affected. FIG. 6D shows the result of such a compensation of charging effects, with the pupil distribution being centered at the optical axis 203.

FIG. 6E shows another example of a first pupil monitor 273. In this example, an electron detector 254 is arranged upstream of the aperture stop 271, wherein the electron detector 254 comprises an aperture opening 289 with diameter D1 exceeding the diameter of aperture stop 271. A plurality of secondary electron beamlets is propagating in direction of the optical axis 203 (upwards in FIG. 6E) and passes the aperture opening 289 before it passes aperture filter 271. In case the plurality of secondary electron beamlets 9 are decentered, the intensity distribution 17 in the pupil plane 258 is decentered by displacement vector 263, and secondary electrons impact on the aperture filter 271. Thereby, backscattered electrons as well as tertiary electrons are generated, which are at least partially collected by electron detector 254 to generate a signal. To reduce background noise, the electron detector 254 can be set to a negative voltage of for example 20V to 50V. Thereby, low energy electrons are repelled from the electron detector and only backscattered electrons from the plurality of secondary electron beamlets 9 are collected. In order to enhance the backscattered electron yield, the aperture stop 271 can be provided with a metal coating, for example with Aluminum, Copper, Gold or Silver.

In the example of FIG. 6E, the electron detectors 254 comprises four segments 254.1 to 254.4 (see also FIG. 6F), wherein each segments generates a signal current corresponding to backscattered secondary or tertiary electron 287. From the four signals, a displacement vector DPx, DPy is generated by

$$DPx = a * Ix + c * {Ix}^{3} \qquad ( 1 a )$$

$$DPy = a * Iy + c * {Iy}^{3} \qquad ( 1 b )$$

$$with$$

$$Ix = ( I 1 - I 3 ) / ( I 1 + I 3 ) \qquad ( 2 a )$$

$$and$$

$$Iy = ( I 2 - I 4 ) / ( I 2 + I 4 ) . \qquad ( 2 b )$$

FIG. 6G illustrates the function Ix in dependency of pupil displacement DPx; the signal Ix shows a nonlinearity, which is considered in equation (1a) by third order component with coefficient b; linear coefficient a and third order coefficient c are determined during a calibration.

FIG. 6H illustrates another example of a first pupil monitor 273 at the example with an electron detector 254. However, the example is not limited to an electron detector 254 but can also be implemented with the absorber electrodes 276 illustrated in FIG. 6C. Instead of a single ring of electron detectors 254.1 to 254.4, the pupil monitor 273 of FIG. 6H comprises at least two rings of individual detectors 254.1 to 254.8. Thereby, a diameter or shape of a pupil distribution can be determined and a determination of a displacement vector 263 can be improved in presence of pupil diameters of variable size or shape. For example, a diameter W of a pupil distribution of the plurality of secondary electron beamlets 9 can be determined according to

$$W = c 0 + c 1 * Iw \qquad ( 3 )$$

$$with$$

$$Iw = ( ( I 5 + I 6 + I 7 + I 8 ) - ( I 1 + I 2 + I 3 + I 4 ) ) / ( ( I 5 + I 6 + I 7 + I 8 ) + ( I 1 + I 2 + I 3 + I 4 ) ) \qquad ( 4 )$$

with signal Ii corresponding to a detector element 254.i with i=1 . . . 8.

The determination of a displacement DPx, DPy can be improved by

$$DPx = a * Ix + b * Iw * Ix + c * {Ix}^{3} \qquad ( 5 a )$$

$$DPy = a * Iy + b * Iw * Iy + c * {Iy}^{3} \qquad ( 5 b )$$

Other parameters as for example ellipticity E can be determined, for example an eccentricity of a pupil distribution of circular shape can be determined according

$$E = ( I 1 + I 3 ) / ( I 2 + I 4 ) . \qquad ( 6 )$$

The example is illustrated with four quadrants two ring segments, but it is not limited thereto. For example, eight angular segments and more three rings of detectors are possible as well. With the pupil information obtained by pupil monitor 273, a beam deviation due to charging can be detected during use, wherein a beam deviation can comprise at least one of a displacement of the pupil distribution of the plurality of secondary electrons, a change of a diameter of the pupil distribution of the plurality of secondary electrons, a change of a shape of the pupil distribution of the plurality of secondary electrons. From the beam deviation, a control signal can be computed, and a beam deviation can be compensated during an image scanning operation.

The electron detector 254 is arranged in a direction such that its sensitive side is facing opposite to the propagation direction of the plurality of secondary electron beamlets 9, and for example set to a negative bias voltage to diffuse lose energy electrons. In the example shown in FIG. 6E, the electron detector 254 is arranged upstream of a pupil plane or cross over 258, but the electron detector 254 is not limited thereto and can also arranged at other positions within the beampath 13 of secondary electrons. Thereby, generally backscattered electrons of a similar kinetic energy of the secondary electrons can be detected and a beam deviation of the plurality of secondary electron beamlets 9 can be detected.

In some examples, the secondary electron beamlets 9.i and 9.o also show a displacement or distortion, such that the focus spots 15.i and 15.o of the secondary electron beamlets 9.i and 9.o are laterally displaced at the secondary electron image plane 225. An adjustment of a displacement with the first multi-pole corrector 220a arranged in close to an intermediate image plane 265 is not possible. A displacement, however, can be adjusted with the second or third multi-pole correctors 220b and 220c. With the combined action of at least two multipole 220a, 220b or 220c, an intensity distribution in a pupil or cross-over plane 258, a position of the plurality of focus spots 15 and a distortion of the plurality of focus spots 15 in the secondary electron image plane 225 can be adjusted. Thereby, a further charging effect of the sample 7 can be compensated.

In an example, the cross-over detection system 273, the cross-over actuation mechanism 220, both connected to a contrast control module 870, form a closed loop operating system. With the combined action of at least two multipole correctors 220a, 220b or 220c, an intensity distribution in a pupil or cross-over plane 258, a position of the plurality of focus spots 15 and a distortion of the plurality of focus spots 15 in the image plane 255 is maintained at a predefined position during operation, for example during scanning image acquisition by a closed loop feedback operation.

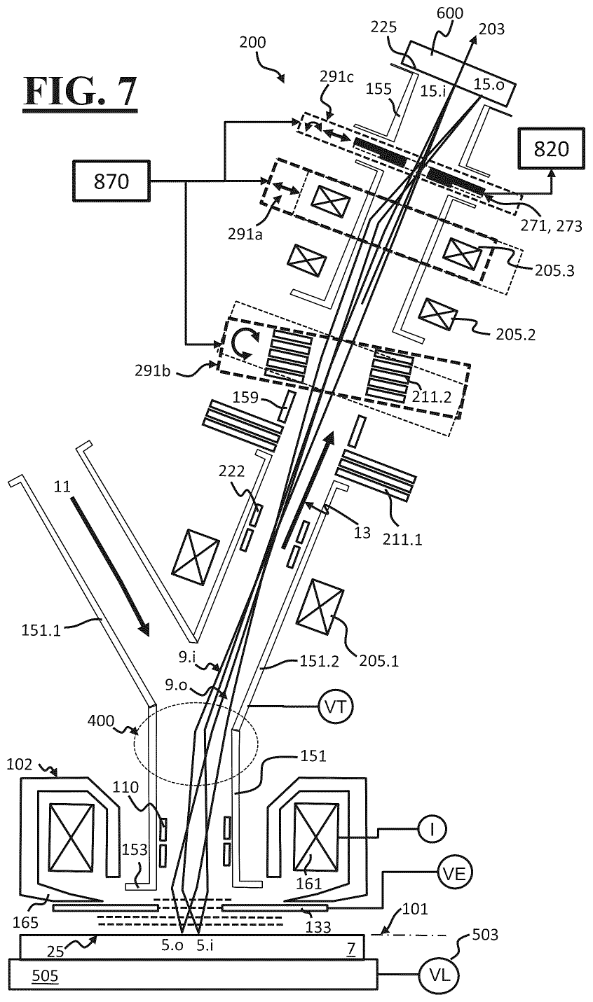

FIG. 7 illustrates a second embodiment. FIG. 7 shows a detection unit 200 with similar components as explained in conjunction with FIG. 5, which are labelled with same reference numbers, and reference is made to the description of FIG. 5. The difference of the second embodiment is given by a different cross-over actuation mechanism, which comprising at last one mechanical actuator. The at least one mechanical actuator can be a mechanical actuator 291a, 291c for affecting a lateral displacement of an optical element 205.3 or the aperture stop 271. The at least one mechanical actuator can also be a mechanical actuator 291b for affecting a rotation of an optical element 211.1 around an axis perpendicular to the optical axis 203. By tilting or displacing imaging optical elements 205.3 and 211.1, a displacement 263 of a pupil distribution 17 can be compensated. By adjusting a lateral position of the aperture stop 273, the lateral position of the aperture stop 271 can be adjusted to a displaced pupil distribution 17 and a symmetrical filtering is enabled. The cross-over detection system 273 of the example in FIG. 7 can be a system shown and described above in FIG. 6. With the system according to the second embodiment, an adjustment of the detection unit 200 is enabled by at least one mechanical actuator 291 instead of at least one multi-pole deflector 220; thereby, a system according to the second embodiment involves less optical elements and is of less electron-optical complexity.

In an example, the cross-over actuation mechanism comprises a combination of at least one mechanical actuator 291 and at least one multi-pole deflector 220. In an example, a further multi-pole deflector 220d can be arranged downstream of the aperture stop 271 (see FIG. 5). In an example, the cross-over actuation mechanism comprises a combination of at least one mechanical actuator 291c for a displacement of the aperture stop 271. After a displacement of the aperture stop, an angle of incidence of the secondary electron beamlets 9 at the secondary electron image plane 225 might be changed and the secondary electron beamlets 9 might not be perpendicular the secondary electron image plane 225. With the further multi-pole deflector 220d downstream of the aperture stop 271, an angle of incidence of the secondary electron beamlets 9 on the secondary electron image plane 225 can be adjusted.

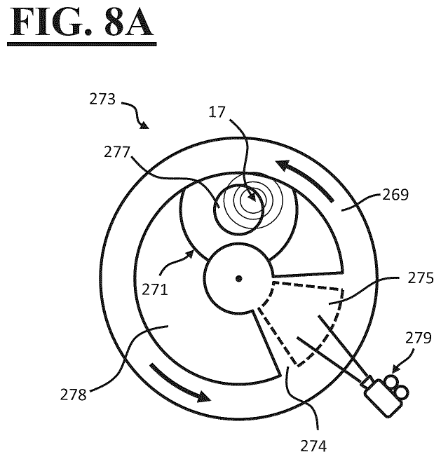

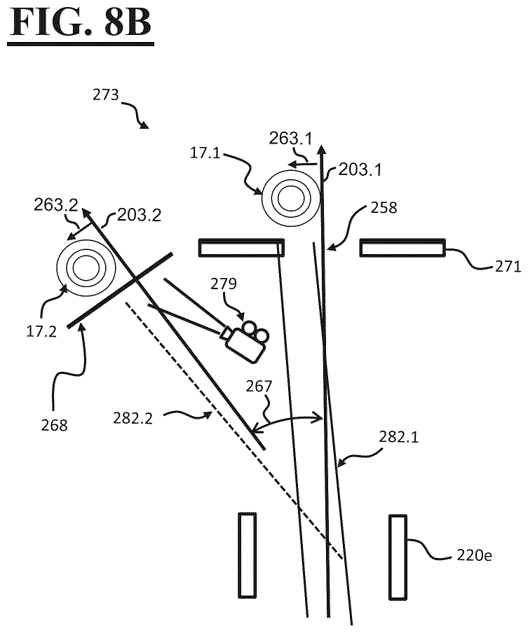

FIGS. 8A-8B illustrates a third embodiment of a detection unit 200 with a cross-over detection system 273. In a first example illustrated in FIG. 8A, the cross-over detection system 273 comprises a scintillator disk, which can be positioned and retracted from a pupil or cross-over plane 258 (see FIG. 5 for reference). The example of FIG. 8A shows a spinning wheel 269, but other positioning systems are possible as well. The spinning wheel 269 has an opening 278 for passing the secondary electron beamlets 9 and a scintillator 275 in one opaque segment 274 of the spinning wheel. During the time when the opaque segment 274 with the scintillator coating 275 covers the aperture stop 271, an image of the pupil distribution 17 is formed on the scintillator coating 275, which can be observed by the camera 279. The rotation speed and segment size of the spinning wheel 269 is configured and synchronized with a scanning operation of the charged particle beamlets. The spinning wheel 269 can be arranged upstream of the aperture stop 271 or downstream in propagation direction of the secondary electron beamlets 9.

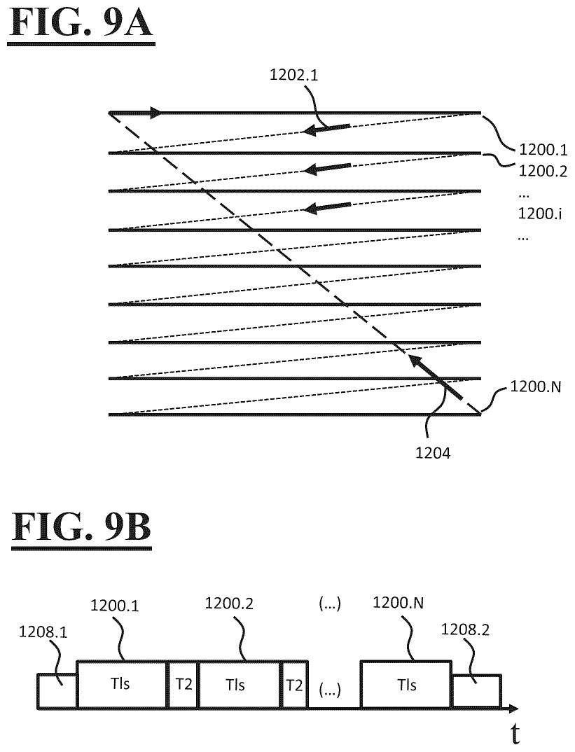

FIG. 8B shows another example of a cross-over detection system 273 configured for an interlaced operation. The cross-over detection system 273 comprises a separate scintillator area 275 on a second monitoring plane 268 for example adjacent to the aperture stop 271. The detection unit 200 further comprises a deflector 220e, by which each secondary electron beamlet 9 is deflected from a first trajectory 282.1 to a second trajectory 282.2. During calibration, a reference axis 203.2 and a deflection angle 267 to the secondary electron beam axis 203.1 of the detection unit 200 is determined. During imaging of a charging sample, a lateral displacement 263.2 of the pupil distribution 17.2 is measured by camera 279 in the second monitoring plane 268 and the lateral displacement 263.1 of the pupil distribution 17.1 at cross-over plane 258 is derived by sensor module 820. A cross-over detection system 273 according to the third embodiment can be operated during a scanning image acquisition. A typical scanning image acquisition for each primary charged particle beamlet 3 by scanning deflector 110 is illustrated in FIG. 9A. Each primary charged particle beamlet 3 is scanned over the surface 25 of the sample 7 according to a scan pattern, comprising a plurality of image scanning lines 1200.1 to 1200.N. At each end of image scanning line 1200.i, each primary charged particle beamlet 3 is deflected by scanning deflector 110 to the start point of a subsequent scanning line 1200.i+1. This scanning operation is also called flyback, forming a plurality of flyback lines 1202.1 to 1202.N−1. At the end of the last scanning line 1200.N, a reset 1204 may follow and each primary charged particle beamlet 3 is scanned by scanning deflector 110 back to the starting point of the first scanning line 1200.1. FIG. 9B shows a corresponding timeline. During a first non-imaging period 1208.1, a cross-over detection system 273 can be calibrated. During each time interval Tis, an image scanning of an image scanning lines 1200.1 to 1200.N is performed. During each time interval T2, a fly-back is performed and cross-over detection system 273 can be switched to an image acquisition of the pupil distribution 17. The rotation frequency of the spinning wheel 269 of FIG. 8A can for example adjusted to a frequency 1/(TIs+TS). During each flyback, the secondary electron beamlets 9 can for example be deflected by scanning deflector 220e by deflection angle 267 to the scintillator 275. The detection unit 200 with a cross-over detection system 273 according to the third embodiment allows therefore a determination of a pupil distribution 17 of the plurality of secondary electron beamlets 9 interlaced within a scanning image acquisition. Time intervals before the scanning the first image scanning line 1200.1 and after the last image scanning line 1200.N can be used for calibration of the cross-over detection system 273.

A system can also comprise a first cross-over detection system 273.1 for continuous monitoring of a pupil distribution 17 and a second cross-over detection system 273.2 for interlaced operation. FIG. 5 illustrates a detection unit 200 comprising a first cross-over detection system 273.1 according to the example illustrated in FIG. 6 and a second cross-over detection system 273.2 according to the third embodiment. While the first cross-over detection system 273.1 is configured for a continuous monitoring of a displacement of the pupil distribution 17 by acquiring an image of the part of the pupil distribution which does not pass the aperture filter opening 277, the second cross-over detection system 273.2 is further configured to acquire a complete image of the pupil distribution 17 for a further determination of a shape and position of the pupil distribution 17.

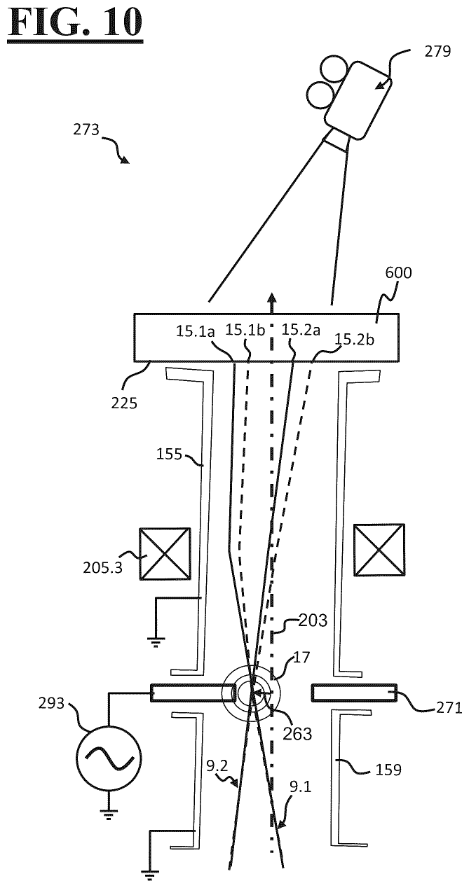

FIG. 10 illustrates a further example of a pupil monitor 273. In this example, the aperture stop 271 is connected to a voltage source 293. By application of a voltage to the aperture stop 271, a kinetic energy of a secondary electron beamlet 9.1 is changed. In the examples illustrated in FIG. 5 or 7, the aperture stop 271 is embedded between beam tube segments 159 and 155, which are set to for example ground level. Aperture stop 271 at a voltage different from the voltage provided to the tube segments 159 and 155 form therefore an electrostatic Einzel lens. A plurality of secondary electron beamlets 9 passing the aperture stop 271 on the optical axis 203 experiences by a voltage change of aperture stop 271 no deflection. However, if the plurality of secondary electron beamlets 9 passes the aperture stop 271 with a displacement 263 from the optical axis 203, the Einzel lens, generated by aperture stop 271 at a voltage different from the voltage provided to the tube segments 159 and 155, causes a deflection of the plurality of secondary electron beamlets 9 such that the plurality of focus spots 15 are displaced in the secondary electron image plane 225. For example, if a displacement 263 of the pupil distribution 17 at cross over 258 is present, a voltage offset provided to the aperture stop 271 induces a position change of a focus spot 15.1a to a position of a focus spot 15.1b. In an example, the image sensor 600 includes a monitoring system 230 with a scintillator and a camera 279 for monitoring the position of the plurality of focus spots 15 of the secondary electron beamlets 9. After application of a voltage by voltage source 293, a displacement of focus spots 15.ia to 15.ib can be detected by monitoring system 230.

From the displacements of the focus spots 15.ia to 15.ib, a displacement 263 of the pupil distribution 17 at cross-over plane 258 can be determined. By application of for example an oscillating voltage via voltage source 293 to the aperture stop 271, a displacement 263 can be determined during use and a compensation of a charging effect can be triggered.

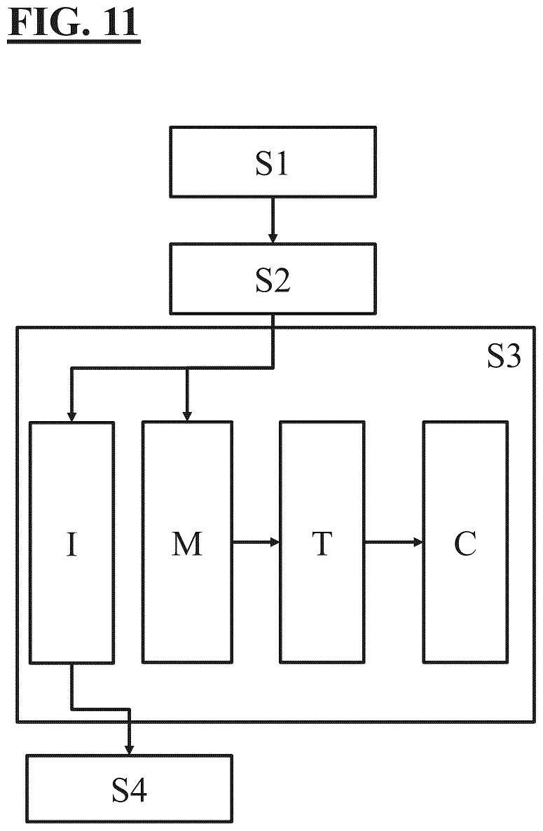

A method of operation of a multi-beam charged particle beam system is described in a fourth embodiment. An example of the fourth embodiment is illustrated in FIG. 11.

In step S1, a wafer 7 is placed on the sample mounting platform 505 and an inspection position on the upper surface 25 of the wafer 7 is positioned in the image plane 101 by stage 500. Step S1 further comprises the selection of an imaging setting for an inspection task. The selected image setting for performing an inspection task comprises a set of imaging parameters, for which a multi-beam charged particle beam system can be adjusted for. For example, one imaging parameter is the landing energy EL of primary charged particles, which is for example selected according to a desired resolution of an inspection task. Further image parameters comprise
the magnification of the object irradiation unit, by which a first pitch between the primary charged particle beamlets in an image plane 101 is adjusted and the magnification of the detection unit 200, such that the secondary electron beamlets 9 are focused on corresponding detection elements at a given second pitch within the image sensor 600;
the position of the image plane 101 of the object irradiation unit 100, for example by adjustment of a working distance WD between a reference plane of the objective lens 102 and image plane 101;
a numerical aperture of each of the plurality of primary charged particle beamlets in the image plane 101;
a beam current and scanning speed, which is for example selected according to a desired image noise level.

In step S2, the multi-beam charged particle beam system 1 is adjusted according to the imaging setting selected in step S1. Step S2 comprising an adjustment of the charged-particle multi-beamlet generator 300, the object irradiation unit 100 and the detection unit 200. The quasi-static adjustment is controlled and executed by primary beam-path control module 830, secondary beam-path control module 840 and stage control module 850. The adjustment of a selected image setting comprises the adjustment of the landing energy EL of primary charged particles by stage control module 850. In an example, the adjustment of the imaging setting further comprises an adjustment of an axial or lateral position or a tilt angle of at least one electro-optical element by a positioning actuator 291. All adjustment values, such as the quasi-static voltages and currents can be predetermined during a calibration operation of the multi-beam charged particle beam system 1 and can be stored for each calibrated image setting in memory 890 of the control unit 800.

In step S3, an inspection is performed with the image setting at the inspection position. The inspection comprises an imaging scanning acquisition step I and a parallel monitoring step M. During the imaging scanning acquisition step I, the plurality of primary charged particle beamlets 3 are scanned by collective multi-beam raster scanner 110 and in parallel, image data are received by image detector 600. During imaging scanning acquisition step I, the second raster scanner 222 is operated to keep the focus spots 15 of secondary electron beamlets 9 at fixed positions at the image sensor 600. During monitoring step M, the position of the pupil distribution 17 of the secondary electron beamlets 9 is monitored and a displacement 263 is determined. The monitoring step M is performed by cross-over detection system 237 and sensor module 820. The displacement 263 is transferred into compensation signals in step T. In a parallel and fast compensation step C, the compensation signals are provided to the cross-over actuation mechanism 229, which comprise a multi-pole deflector 220 and/or positioning actuators 291. For example, compensation step C comprises an operation of at least one multipole deflector 220. For example, compensation step C comprises an operation of a position or tilt actuator 291 of an optical element 205 or 211 or of an aperture stop 271. In an example of step T, the compensation signals are selected according to at least one preselected cross-over actuation mechanism 229. The monitoring step M, transfer step T and adjustment step C are continuously running and executed continuously during the scanning image acquisition step I and performed during an image scanning operation. During an image scanning operation, an image scanning is for example performed at a scanning frequency of 20 MHz or more, for example 50 Mhz or 80 MHz. A compensation of charging effects including monitoring step M, transfer step T and compensation step C is typically only limited by the monitoring step M, comprising the acquisition of the displacement 263 of the pupil distribution 17 of the secondary electron beamlets 9. In an example, during a monitoring step M, a displacement 263 of a pupil distribution 17 of the plurality of secondary electron beamlets 9 is determined during a fly-back interval T2 of a scanning image acquisition. In an example, during a monitoring step M a displacement 263 of a pupil distribution 17 of the plurality of secondary electron beamlets 9 is continuously determined by a cross-over detection system 273 comprising a scintillator 275 or absorber coating segments 276 arranged in the circumference of an aperture filter opening 277. In an example, during a monitoring step M, next to a displacement 263 of a pupil distribution 17 of the plurality of secondary electron beamlets 9, a shape or a diameter of the pupil distribution 17 of the plurality of secondary electron beamlets 9 are continuously determined by a cross-over detection system 273, for example a cross-over detection system 273 comprising a plurality of backscattered electron detectors 254. With the monitoring, transfer, and compensation steps during and parallel to scanning image acquisition step I, a sample charging effect is continuously and dynamically compensated.

In step S4, the image data obtained in scanning image acquisition step I is stored and further processed, for example a stitching operation is performed, or different image post-processing operations are performed. The image data can be further processed, depending on different desired properties of applications. Further processing can comprise pattern detection, image feature extraction, or image feature classification or the like.

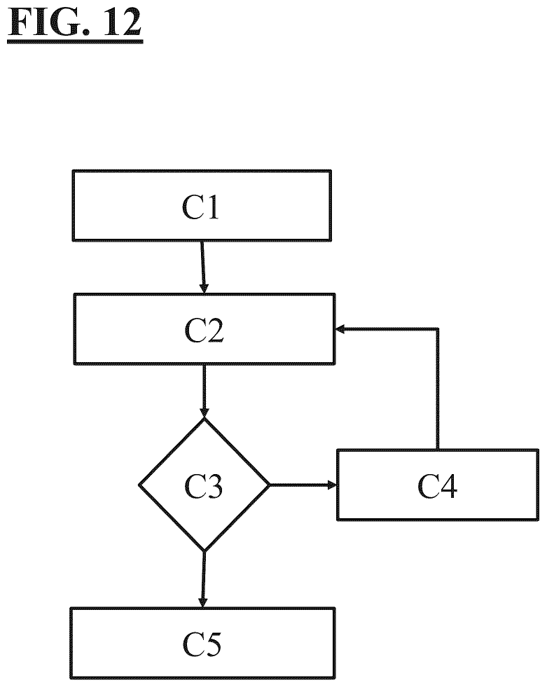

A detection unit 200 of a multi-beam charged particle beam system 1 according to the disclosure comprises a cross-over detection system and a cross-over actuation mechanism, which are both connected to a contrast control module. The cross-over detection system generates during use a signal representing a displacement of a pupil distribution of the plurality of secondary electron beamlets. The cross-over actuation mechanism is configured to adjust a position of the pupil distribution and thereby compensate a displacement of the pupil distribution. In order to achieve a compensation of a displacement of the pupil distribution, cross-over detection system and cross-over actuation mechanism are calibrated and a transfer relationship between a sensor signal generated by the cross-over detection system to a control signal to control a cross-over actuation mechanism is determined. A method for calibration and determination of the transfer relationship is given according to a fifth embodiment. The transfer relationship is for example a linear relationship between sensor signal and control signal with a linear coefficient determined during a calibration. Higher-order, non-linear dependencies are possible as well (see above, eq. 1). FIG. 12 illustrates a method according to a fifth embodiment.

In step C1, a calibration object is placed in the image plane of the multi-beam charged particle beam system 1 and a scanning image is acquired. For a given and known calibration object, an ideal pupil distribution is expected, with an ideal, circular pupil distribution 17 centered on an optical axis 203.

In step C2, a signal from a cross-over detection system 273 is measured and analyzed. The analysis comprises an analysis of the symmetry of the signals generated from several absorber segments 276, or a position determination of a center of gravity of an image of a pupil distribution 17 detected by camera 279.

In a first example, a first pair of signals generated by a first cross-over detection system 273.1 and a second cross-over detection system 273.2 are obtained, and the signals are correlated. In a second example, an image contrast of an image of the known calibration object is analyzed. For a known calibration object, for example an isotropic contrast is expected, and a deviation of an isotropic contrast is correlated to a displacement of the pupil distribution.

In step C3, an optimization of a position of a pupil distribution is performed. In step C4, a control signal is provided to a cross-over actuation mechanism 220, 291 and step C2 is repeated, and a change to the first signal is determined. The process is repeated for example two or three or more times for each degree of freedom, and a transfer relationship between a sensor signal generated in steps C2 and control step C4 is determined in step C5. A transfer relationship can for example be a transfer matrix for a transfer of an input signal comprising a plurality of individual signals to a plurality of control signal to be provided during use to at least one cross-over actuation mechanisms 220, 291. The transfer relationship is stored in a memory of the contrast control unit 870.

With the method according to the fifth embodiment, a detection unit 200 comprising at least one a cross-over actuation mechanism 220, 291 can be calibrated and initially adjusted for acquisition of an isotropic image contrast during use. With the method according to the fifth embodiment, a detection unit 200 comprising at least one a cross-over actuation mechanism 220, 291, a cross-over detection system 273 and a contrast control module 870 can be calibrated to for acquisition of an isotropic image contrast during use even in case of charging objects. With the method according to the fifth embodiment, a detection unit 200 comprising at least one a cross-over actuation mechanism 220, 291, a cross-over detection system 273 and a contrast control module 870 can be calibrated to for a compensation of a charging effect during an image acquisition.

The disclosure can be described by following clauses:

Clause 1: A detection unit (200) of a multi-beam charged particle beam system (1), comprising
at least one imaging lens (205) for forming a plurality of focus spots (15) of a plurality of secondary electron beamlets (9) generated during use in an secondary electron image plane (225) of the detection unit (200),
an aperture stop (271) arranged in a cross-over or pupil plane (258) of the detection unit (200) for filtering the plurality of secondary electron beamlets (9) within the cross-over or pupil plane (258),
a contrast control unit (870),
a cross-over detection system (227) connected to the contrast control unit (870), configured to generate during use a measurement signal of at least a lateral position of a pupil distribution (17) of the plurality of secondary electron beamlets (9) within the cross-over or pupil plane (258) and to provide during use the measurement signal to the contrast control unit (870),
at least one cross-over actuation mechanism (229) connected to the contrast control unit (870), configured to receive at least one driving signal from the contrast control unit (870) for adjusting the lateral position of the pupil distribution (17) within the cross-over or pupil plane (258),
   wherein
the contrast control unit (870) is configured to determine from the measurement signal a displacement (263) of the pupil distribution (17) with respect to an optical axis (203) of the detection unit (200), and to determine the at least one driving signal from the displacement (263).

Clause 2: The detection unit (200) of clause 1, wherein the cross-over actuation mechanism (229) is formed by at least one member of a group including a multi-pole deflector (220, 220a, 220b, 220c, 220d), a tilt actuator (291b) of a lens element (205, 211), a position actuator (291a, 291c) of a lens element (211, 205) or of the aperture stop (271).

Clause 3: The detection unit (200) of clause 2, wherein the cross-over actuation mechanism comprising at least one deflector (220, 220a, 220b, 220c, 220d), configured to adjust a lateral position of the pupil distribution (17) of the plurality of secondary electron beamlets (9) while keeping the focus points (15) of each of the plurality of secondary electron beamlets (9) at the secondary electron image plane (225) at a predefined and constant position.

Clause 4: The detection unit (200) of clause 3, wherein the cross-over actuation mechanism comprises one deflector (220a) arranged in an intermediate image plane (265) of the detection unit (200).

Clause 5: The detection unit (200) of clause 3, wherein the cross-over actuation mechanism comprises at least a first and a second deflector (220, 220a, 220b, 220c, 220d), configured to adjust a lateral position of the pupil distribution (17) of the plurality of secondary electron beamlets (9) while keeping the focus points (15) of each of the plurality of secondary electron beamlets (9) at the secondary electron image plane (225) at a predefined and constant position.

Clause 6: The detection unit (200) of clause 1 or 2, wherein the cross-over actuation mechanism comprising a position or tilt actuator (291a, 291b, 291c) configured for changing the axial position or tilt angle of at least one movable element of the detection unit (200) while keeping the focus points (15) of each of the plurality of secondary electron beamlets (9) at the secondary electron image plane (225) at a predefined and constant position.

Clause 7: The detection unit (200) of clause 6, wherein the at least one movable element is the

aperture stop (271) mounted on a position actuator (291c).

Clause 8: The detection unit (200) of clauses 6 or 7, wherein the cross-over actuation mechanism comprising at least a first and a second position or tilt actuator (291a, 291b) of a first and a second lens element (205.3, 211.2).

Clause 9: The detection unit (200) of any of the clauses 1 to 8, wherein the cross-over detection system (227) comprising at least one member of a group including a scintillator coating (275) and a monitoring camera (279), a plurality of absorber segments (276) connected to ampere meters (272), a retractable detection system (273.2), a spinning wheel (269), a voltage supply (293), a deflector (220e), or a backscattered electron detector (254).

Clause 10: The detection unit (200) of any of the clauses 1 to 9, wherein the cross-over detection system (227) comprising the scintillator coating (275) in the periphery of an opening (277) of the aperture stop (271) and a monitoring camera (279).

Clause 11: The detection unit (200) of any of the clauses 1 to 9, wherein the cross-over detection system (227) comprising a plurality of absorber segments (276) connected to ampere meters (272).

Clause 12: The detection unit (200) of any of the clauses 1 to 9, wherein the cross-over detection system (227) comprising a plurality of backscattered electron detectors (254) arranged upstream of the aperture stop (271).

Clause 13: The detection unit (200) of any of the clauses 1 to 9, wherein the cross-over detection system (227) comprising the deflector (220e) configured to deflect the plurality of secondary electron beamlets (9) on a second monitoring plane (268) and a monitoring camera (279).

Clause 14: A multi-beam charged particle beam system (1) comprising
an object irradiation unit (100) for forming a plurality of primary focus spots (5) in an image plane (101),
a wafer stage (500) configured for holding and positioning during use a surface (25) of a wafer (7) in the image plane (101),
a detection unit (200) according to any of the clauses 1 to 13.

Clause 15: A method of operating a multi-beam charged particle system (1), comprising a detection unit (200) configured to image a plurality of secondary electron beamlets (9) excited during use from a surface (25) of a wafer (7) and to from a plurality of focus spots (15) of the plurality of secondary electron beamlets (9) in an secondary electron image plane (225) of the detection unit (200), comprising
starting and performing of a scanning image acquisition,
detecting an pupil distribution (17)) of the plurality of secondary electron beamlets at a cross-over plane (258) with a cross-over detection system during the image acquisition,
adjusting a lateral position of pupil distribution (17) while keeping the focus points (15) of each of the plurality of secondary electron beamlets (9) at the secondary electron image plane (225) at a predefined and constant position.

Clause 16: The method of clause 15, comprising selecting an imaging setting including selection of a landing energy EL of primary charged particles.

Clause 17: The method of clause 15 or 16, comprising adjusting a deceleration field (237) close to the surface (25) of a wafer (7) and at least one lens power of at least one magneto-dynamic projection lens (205) of the detection unit (200) to the selected landing energy EL.

Clause 18: The method of any of the clauses 15 to 17, wherein the step of detecting the pupil distribution (17) at a cross-over plane (258) with a cross-over detection system is performed during a fly-back time T2 of the scanning image acquisition.

Clause 19: The method of any of the clauses 15 to 17, wherein the step of detecting the pupil distribution (17) is continuously performed during the scanning image acquisition.

Clause 20: A multi-beam charged particle beam system (1) comprising
an object irradiation unit (100) for forming a plurality of primary focus spots (5) in an image plane (101),
a wafer stage (500) configured for holding and positioning during use a surface (25) of a wafer (7) in the image plane (101),
a detection unit (200),
a contrast control unit (870), configured to execute a method according to any of the clauses 15 to 19.

Clause 21: A multi-beam charged particle beam system (1) comprising
an object irradiation unit (100) for forming a plurality of primary focus spots (5) in an image plane (101),
a wafer stage (500) configured for holding and positioning during use a surface (25) of a wafer (7) in the image plane (101),
a detection unit (200), comprising a backscattered electron detector (254) with an aperture (289) for transmission of a plurality of secondars beamlets (9) and configured to detect secondary electrons which are backscattered within the secondary electron beam path (13).

Clause 22: The multi-beam charged particle beam system (1) according to clause 21, wherein the backscattered electron detector (254) comprises at least a first ring of detectors with at least four backscattered electron detectors (254.1) to (254.4) in arranged four quadrants.

Clause 23: The multi-beam charged particle beam system (1) according to clause 22, wherein the backscattered electron detector (254) comprises a second ring of detectors with at least four backscattered electron detectors (254.5) to (254.8) in arranged four quadrants.

Clause 24: The multi-beam charged particle beam system (1) according to any of the clauses 21 to 23, wherein the backscattered electron detector (254) is arranged upstream of an aperture filter (271) and configured to detect secondary electrons backscattered from the aperture filter (271).

Clause 25: The multi-beam charged particle beam system (1) according to clause 24, further comprising a control unit (800) configured to determine, from a signal provided by the backscattered electron detector (254), at least one of a displacement, a change of a diameter or a change of a shape of a pupil distribution (17) of a plurality of secondary electron beamlets (9).

The disclosure is however not limited to the embodiments or clauses described above. The embodiments or examples can be fully or partly combined with one another, and various modifications within the scope of any person of ordinary skill in the art are covered by the embodiments and examples of the disclosure.

A list of reference numbers is provided:

1 multi-beamlet charged-particle system

3 primary charged particle beamlets, or plurality of primary charged particle beamlets

5 primary charged particle beam spot

7 object or sample

9 secondary electron beamlet, forming the plurality of secondary electron beamlets

11 primary beam path

13 secondary electron beam path

15 secondary charged particle focus spot

17 pupil distribution

19 image of pupil distribution

25 surface of object or sample

67 first material composition

69 second material composition

100 object irradiation unit

101 image plane

102 objective lens

103 field lens

108 first beam cross over

110 collective multi-beam raster scanner

133 electrode

135 first electric field

137 second electric field

139 extraction field vector

141 interaction volume

143 scanning direction

147 virtual interaction volume

149 scanned surface segment

151 beam tube

153 Beam exit opening

155 third tube segment

159 second tube segment

161 coil

163 pole shoe

165 lower pole shoe segment

191 secondary electron trajectory

193 secondary electron trajectory

200 detection unit

203 optical axis of detection unit

205 imaging lens

211 fast correction lenses

220 multipole deflector

222 second raster scanner

225 secondary electron image plane

227 cross-over detection system

229 cross-over actuation mechanism

230 monitoring system

232 high resolution sensor

235 imaging lens

237 beam divider mirror

254 electron detector

256 first cross or pupil over position

258 second cross over or pupil position

261 camera image

263 displacement vector

265 intermediate image plane

267 deflection angle

268 second monitoring plane

269 spinning wheel

271 aperture stop

272 ampere meter

273 pupil monitor

274 opaque segment of spinning wheel

275 scintillator coating

276 absorber segments

277 aperture filter opening

278 opening of spinning wheel

279 monitoring camera

281 electron trajectory of axial point with correction

282 electron trajectory of axial point without correction

283 electron trajectory of field point with correction

285 secondary electron trajectory

287 backscattered secondary electron or tertiary electron

289 aperture

291 positioning actuator

293 voltage source

300 charged-particle multi-beamlet generator

301 charged particle source

303 collimating lenses

304 filter plate

305 primary multi-beamlet-forming unit

306 multi-aperture plates

309 primary electron beam

321 intermediate image surface

331 first field lens

333 second field lens

400 beam splitter or divider unit

500 sample stage

503 Sample voltage supply

505 sample mounting platform

600 image sensor

602 electron to photon conversion unit

605 collection lens

607 Folding mirror

609 light beam

611 zoom lens

613 light optical focus point

615 optical fiber

617 position actuator

623 detection element

630 retraction direction

800 control unit

810 imaging control module

820 sensor module

830 primary beam-path control module

840 secondary beam-path control module

850 stage control module

860 scanning control unit

870 contrast control module

880 control operation processor

890 memory

1200 Image scanning line

1202 line flyback

1204 reset

1208 non-imaging period

What is claimed is:

1. A detection unit, comprising:
at least one imaging lens configured to form a plurality of focus spots of a plurality of secondary electron beamlets in a secondary electron image plane of the detection unit;
an aperture stop in a cross-over or pupil plane of the detection unit, the aperture stop configured to filter the plurality of secondary electron beamlets within the cross-over or pupil plane;
a contrast control unit;
a cross-over detection system connected to the contrast control unit, the cross-over detection system configured to: i) generate a measurement signal of a lateral position of a pupil distribution of the plurality of secondary electron beamlets within the cross-over or pupil plane; and ii) provide the measurement signal to the contrast control unit; and
at least one cross-over actuation mechanism connected to the contrast control unit, the at least one cross-over actuation mechanism configured to receive at least one driving signal from the contrast control unit to adjust the lateral position of the pupil distribution of the plurality of secondary electron beamlets within the cross-over or pupil plane,
wherein:
the contrast control unit is configured to determine: i) from the measurement signal, a displacement of the pupil distribution with respect to an optical axis of the detection unit; and ii) the at least one driving signal from the displacement; and
the cross-over detection system comprises a plurality of backscattered electron detectors upstream of the aperture stop.

2. The detection unit of claim 1, wherein the at least one cross-over actuation mechanism comprises at least one member selected from the group consisting of a multi-pole deflector, a tilt actuator of a lens element, a position actuator of a lens element, and the aperture stop.

3. The detection unit of claim 2, wherein the at least one cross-over actuation mechanism comprises at least one deflector configured to adjust the lateral position of the pupil distribution of the plurality of secondary electron beamlets within the cross-over or pupil plane while keeping the focus spot of each secondary electron beamlet at a constant position in the secondary electron image plane.

4. The detection unit of claim 3, wherein the at least one cross-over actuation mechanism comprises a deflector in an intermediate image plane of the detection unit.

5. The detection unit of claim 3, wherein the at least one cross-over actuation mechanism comprises first and second deflectors configured to adjust the lateral position of the pupil distribution of the plurality of secondary electron beamlets within the cross-over or pupil plane while keeping the focus spot of each secondary electron beamlets at a constant position in the secondary electron image plane.

6. The detection unit of claim 1, wherein the at least one cross-over actuation mechanism comprises an actuator selected from the group consisting of a position actuator and a tilt actuator, the actuator configured to change an axial position or a tilt angle of at least one movable element of the detection unit while keeping the focus spot each secondary electron beamlets at a constant position in the secondary electron image plane.

7. The detection unit of claim 6, wherein the at least one movable element comprises the aperture stop, and the aperture stop is mounted on a position actuator.

8. The detection unit of claim 6, wherein the cross-over actuation mechanism comprises a first actuator of a first lens element and a second actuator of a second lens element, the first and second actuators comprising position actuators or tilt actuators.

9. A multi-beam charged particle beam system, comprising:
an object irradiation unit configured to form a plurality of primary focus spots in an image plane; and
a detection unit according to claim 1.

10. A method of operating a multi-beam charged particle system, the system comprising a detection unit configured to image a plurality of secondary electron beamlets from a surface of an object, the detection unit configured to form a plurality of focus spots of the plurality of secondary electron beamlets in a secondary electron image plane of the detection unit, the method comprising:
starting and performing of a scanning image acquisition;
during the image acquisition, detecting a pupil distribution of the plurality of secondary electron beamlets in a cross-over plane with a cross-over detection system; and
adjusting a lateral position of pupil distribution while keeping the focus spot of each secondary electron beamlet at a constant position in the secondary electron image plane.

11. The method of claim 10, further comprising selecting an imaging setting which comprises a landing energy of primary charged particles.

12. The method of claim 10, further comprising adjusting a deceleration field close to the surface of the object and at least one lens power of at least one magneto-dynamic projection lens of the detection unit to the selected landing energy EL.

13. The method of claim 10, comprising detecting the pupil distribution of the plurality of secondary electron beamlets in the cross-over plane with the cross-over detection system during a fly-back time of the scanning image acquisition.

14. The method of claim 10, wherein detecting the pupil distribution is continuously performed during the scanning image acquisition.

15. One or more machine-readable hardware storage device comprises instructions that are executable by one or more processing devices to perform operations comprising the method of claim 10.

16. A system, comprising:
one or more processing devices; and
one or more machine-readable hardware storage device comprises instructions that are executable by the one or more processing devices to perform operations comprising the method of claim 10.

17. A multi-beam charged particle beam system, comprising:
an object irradiation unit configured to form a plurality of primary focus spots in an image plane;
a wafer stage configured to hold and position a surface of an object; and
a detection unit comprising a backscattered electron detector, the backscattered electron detector comprising an aperture configured to: i) transmit a plurality of secondary beamlets; and ii) detect secondary electrons which are backscattered within the secondary electron beam path.

18. The multi-beam charged particle beam system of claim 17, wherein the backscattered electron detector comprises a first ring of detectors comprising four backscattered electron detectors disposed in four quadrants.

19. The multi-beam charged particle beam system of claim 18, wherein the backscattered electron detector further comprises a second ring of detectors comprising four backscattered electron detectors disposed in four quadrants.

20. The multi-beam charged particle beam system of claim 17, further comprising an aperture filter, wherein the backscattered electron detector is: i) upstream of an aperture filter; and ii) configured to detect secondary electrons backscattered from the aperture filter.

21. The multi-beam charged particle beam system of claim 20, further comprising a control unit configured to determine, from a signal provided by the backscattered electron detector, at least one member selected form the group consisting of a displacement of the plurality of secondary electron beamlets, a change in a diameter of a pupil distribution of the plurality of secondary electron beamlets, and a change in a shape of a pupil distribution of the plurality of secondary electron beamlets.
